(19) United States
(12) Patent Application Publication
(10) Pub. No.: US 2009/0179327 A1
(43) Pub. Date: Jul. 16, 2009

(54) Packaging structure, method for manufacturing the same, and method for using the same

(76) Inventors: Chung-Er Huang, Taipei (TW); Chih-Hao Liao, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/007,716

(22) Filed: Jan. 15, 2008

(51) Int. Cl. H01L 23/488; H01L 21/58

(52) U.S. Cl. 257/738; 438/118; 257/E23.023; 257/E21.505

(57) ABSTRACT

A packaging structure applied for a surface mounting process, comprising: a chip module having a packaging surface; and a pre-cured layer formed on the packaging surface of the chip module. As above-mentioned, the structure is employed for protecting the external surface of the wafer. The pre-cured layer is formed on pre-curing a gluing material and the gluing material is uniformly filled with the space between the connecting protrusions on the packaging surface. The pre-cured later is post-curing in a connecting process for mounting the connecting protrusions to the substrate so that the connecting strength is improved. Moreover, the rate of the packaging process is increasing.

### BACKGROUND OF THE INVENTION

1. Field of the Invention

The present invention relates to a packaging structure and a method for manufacturing and using the same, and in particular to a packaging structure having a pre-cured layer thereon and a method for manufacturing and using the same.

2. Description of Related Art

As the development of the semiconductor advances, the functions of semiconductor chips become more and more powerful. Due to ever larger data transmission of semiconductor chips, the pins of the chips are increasing. Thus, the packaging technology to protect the chips and delicate chip pins have a direct impact on improving the industry.

Packaging plays an important role for protecting the chip or IC circuit from humidity or collision. Now packaging has to dissipate heat from the chip so as to maintain the environment of the chip in a suitable condition for operation.

However, the conventional packaging structure often has some disadvantages. The metal bumps or solder balls between the chip and the substrate are smaller and smaller because the progress of IC technology requires finer pitch package. Thus a gluing material is added between the chip and substrate for improving the connection between the chip and the substrate. In the conditioning process, the chip is connected with the substrate and then the gluing material is injected into the gap between the chip and the substrate. The gluing material diffuses from edge to center due to the diffusing property and capillary motion. With the decrease of the gap, the gluing material diffuses slowly from the edge to the center. In other words, the diffusing time is increased. Therefore, the time and cost of the packaging process are magnified.

Therefore, in view of this, the inventor proposes the present invention to overcome the above problems based on his expert experience and deliberate research.

### SUMMARY OF THE INVENTION

The primary object of the present invention is to provide for a packaging structure, a method for manufacturing the same and a method for using the same. The packaging structure is provided for improving the reliability of the connection between the chip and the substrate. Furthermore, the packaging processes are optimized.

Another object of the present invention is to increase the throughput of the packaging process.
In order to achieve the above objects, the present invention provides a packaging structure.
The packaging structure comprises: a chip module having a packaging surface; and a pre-cured layer formed on the packaging surface of the chip module.

In order to achieve the above objects, the present invention provides a method for manufacturing the packaging structure. The method comprises (a) providing a chip module having a packaging surface; (b) coating a gluing material on the packaging surface; and (c) pre-curing the gluing material to form a pre-cured layer on the packaging surface.

In order to achieve the above objects, the present invention provides a method for using the packaging structure. The method comprises (a) providing the pre-cured layer of the packaging structure on the substrate; (b) providing a connecting process, wherein the packaging surface has a plurality of connecting protrusions thereon and the connecting process is provided for connecting the connecting protrusions to the substrate; and (c) simultaneously, post-curing the pre-cured layer into an adhesive layer between the chip module and the substrate.

Depending on the present invention, the packaging structure with a pre-cured layer is thus provided for miniaturized electrical device. Furthermore, the packaging efficiency is improved.

In order to better understand the characteristics and technical contents of the present invention, a detailed description thereof will be made with reference to the accompanying drawings. However, it should be understood that the drawings and the description are illustrative but not used to limit the scope of the present invention.

### BRIEF DESCRIPTION OF THE DRAWINGS

FIG. 1 is a schematic view showing packaging structure according to the present invention;

FIG. 2 is a flow chart showing the method for manufacturing the packaging structure according to the present invention;

FIG. 3 is a schematic view showing the second embodiment of the packaging structure according to the present invention;

FIG. 4 is a schematic view showing the packaging structure connected on a substrate after the SMT process according to the present invention; and

FIG. 5 is a flow chart showing the method for using the packaging structure according to the present invention.

### DETAILED DESCRIPTION OF PREFERRED EMBODIMENTS

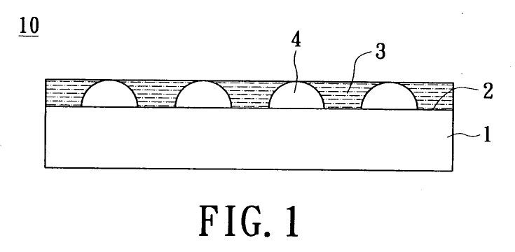

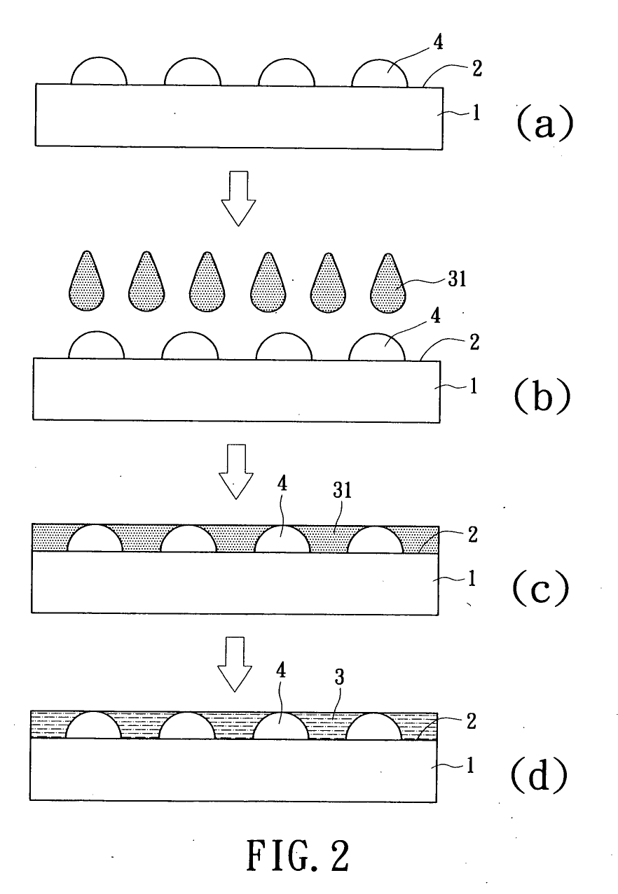

Please refer to FIG. 1, the invention discloses a packaging structure 10 which is applied to a surface mounting technology (SMT) process. The packaging structure 10 comprises a chip module 1 having a package surface 2 and a pre-cured layer 3 formed on the packaging surface 2 of the chip module 1. The chip module 1 can be an IC chip or another electronic module for connecting on the substrate 5 (shown in FIG. 4). The package surface 2 has a plurality of connecting protrusions 4 and the connecting protrusions are metallic protrusions, solder balls, or another connecting means familiar with the skilled person. The pre-cured layer 3 is formed by pre-curing a gluing material 31 (shown in FIG. 2). The gluing material 31 has thermal-forming property and pre-cures at a predetermined temperature. In the embodiment, the gluing material 31 pre-cures at a predetermined temperature higher than room temperature on the package surface 2. Preferably, the gluing material 31 is disposed between the connecting protrusions 4 on the packaging surface 2. Thus, the connecting protrusions 4 are surrounded by the pre-cured layer 3.

Please refer to FIG. 2, A manufacturing method of a packaging structure is disclosed. The manufacturing method comprises the following steps. First step (a) is to provide a chip module 1 having a packaging surface 2 thereon. There is a plurality of connecting protrusions 4 disposed on the packaging surface 2 and the connecting protrusions 4 have discretionary and suitable shapes for the following packaging processes.

In addition, the connecting protrusions 4 and the integral circuit in the chip module 1 are formed by various semiconductor-manufacturing processes, such as lithograph process, etching process and metal deposition process.

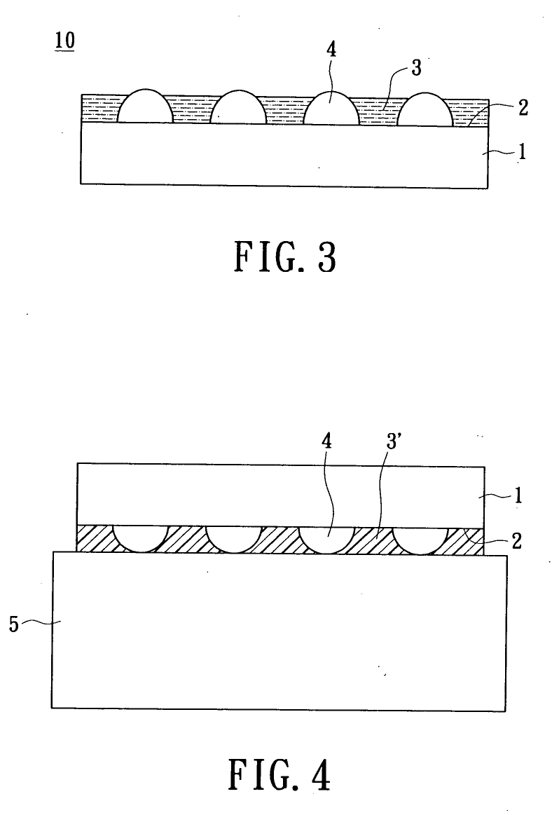

Step (b) is coating the gluing material 31 on the packaging surface 2. The gluing material 31 is mixed or dissolved in a solvent and then is uniformly coated on the packaging surface 2. The thickness of the pre-cured layer 3 can be adjusted by controlling the adhesion and the viscosity of the gluing material 31 so that the pre-cured layer 3 has a predetermined thickness after the gluing material 31 pre-cured. The thickness of the pre-cured layer 3 is controlled according to the application. Please refer to FIG. 2 (d), the thickness of the pre-cured layer 3 can be even with the thickness of the connecting protrusions 4. Alternatively, the thickness of the pre-cured layer 3 is lower than that of the connecting protrusions 4, please refer to FIG. 3. The gluing material 31 is uniformly surrounding the connecting protrusions 4 so that the packaging strength is improved.

FIG. 2 step (c) is pre-curing the gluing material 31 into the pre-cured layer 3. The pre-curing step is provided to remove the solvent in the gluing material 31 and the gluing material 31 is semi-cured to form the pre-cured layer 3. In the embodiment, the gluing material 31 is a thermal-forming polymer and is cured at a predetermined temperature, for example at 50° C., which is higher than the room temperature (about 25° C.). However the gluing material 31 is not restricted to thermal-forming polymer, as the gluing material 31 can also cure under the exposure of UV-light.

Observe FIGS. 3 and 4, a method for packaging package structure 10 is additionally disclosed. The packaging structure 10 provides for connection to the substrate 5 by a connecting process. The pre-cured layer 3 is melted because of the heat produced in the connecting process. Then, the melted pre-cured layer 3 is cooled to post-cure into an adhesive layer 3′ when the connecting process finishes. The adhesive layer 3′ can then be applied for packaging the chip module 1 on substrate 5. The method has the following steps.

Step (a) is to provide packaging structure 10 on substrate 5 then the pre-cured layer 3 is downwardly connected on substrate 5 (shown in FIG. 4).

Step (b) is providing a connecting process. The connecting process is provided for connecting the connecting protrusions 4 with substrate 5. The connecting process can be a welding process. The welding process is provided for connecting the connecting protrusions 4 with substrate 5 via a SMT process. Simultaneously, the pre-cured layer 3 is melted because of the heat in the welding process. Then, the melted pre-cured layer 3 is filled between the packaging surface 2 of the chip module 1 and the substrate 5. At last, the melted pre-cured layer 3 post-cures into an adhesive layer 3′ so as to connect the chip module 1 with the substrate 5.

Accordingly, the present invention provides a packaging structure 10 that can directly produce the finishing packaging processes. The pre-cured layer 3 of the packaging structure 10 is substantially a semi-solid layer which has enough mechanical strength and hardness to be handled directly.

To sum up, the present invention has the following advantages:
1. The gluing material is pre-cured on the package surface so that the gluing material can be post-cured when the chip module is connected on the substrate. Therefore, the reliability of the packaging process is improved and the processes are optimized.
2. The diffusing property of the gluing material is not necessarily required and the cost of the gluing material is reduced.
3. The packaging rate of the prior art is slow because the gluing material has to diffuse from the edge to the center: of the structure with limited space. The present invention provides for an increasing rate of producing.

Although the present invention has been described with reference to the foregoing preferred embodiment, it will be understood that the invention is not limited to the details thereof. Various equivalent variations and modifications may occur to those skilled in this art in view of the teachings of the present invention. Thus, all such variations and equivalent modifications are also embraced within the scope of the invention as defined in the appended claims.

What is claimed is:

1. A packaging structure applied for a surface mounting process, comprising:
a chip module having a packaging surface; and
a pre-cured layer formed on the packaging surface of the chip module.

2. The packaging structure according to claim 1, further comprising a plurality of connecting protrusions disposed on the packaging surface of the chip module wherein the pre-cured layer is formed between the connecting protrusions.

3. The packaging structure according to claim 2, wherein the connecting protrusions are metallic protrusions or solder balls.

4. The packaging structure according to claim 1, wherein the pre-cured layer is formed by pre-curing a gluing material with thermal-forming property.

5. The packaging structure according to claim 1, wherein the pre-cured layer has a predetermined thickness.

6. A manufacturing method of a packaging structure, comprising:
(a). providing a chip module having a packaging surface;
(b). coating a gluing material on the packaging surface; and
(c). pre-curing the gluing material to form a pre-cured layer on the packaging surface.

7. The manufacturing method according to claim 6, wherein the gluing material is disposed between a plurality of connecting protrusions on the packaging surface.

8. The manufacturing method according to claim 6, wherein the gluing material is a thermal-forming material.

9. The manufacturing method according to claim 6, wherein the gluing material is pre-cured at a predetermined temperature higher than room temperature.

10. A method for packaging a packaging structure according to claim 1 on a substrate, comprising:
(a). providing the pre-cured layer of the packaging structure on the substrate;
(b). providing a connecting process, wherein the packaging surface has a plurality of connecting protrusions thereon and the connecting process is provided for connecting the connecting protrusions to the substrate; and
(c). simultaneously, post-curing the pre-cured layer into an adhesive layer between the chip module and the substrate.

11. The packaging method according to claim 10, wherein the connecting process is a welding process.

12. The packaging method according to claim 11, wherein the welding process provides heat to post-cure the pre-cured layer into the adhesive layer.
